(19) United States
(12) Patent Application Publication
(10) Pub. No.: US 2026/0094655 A1
(43) Pub. Date: Apr. 2, 2026

(54) MAINTENANCE-BASED CONDITIONS FOR BLOCK RETIREMENT

(71) Applicant: Micron Technology, Inc., Boise, ID (US)

(72) Inventors: Domenico BALZANO, Torre Annunziata (IT); Domenico PUNZO, Naples (IT)

(21) Appl. No.: 19/293,192

(22) Filed: Aug. 7, 2025

Related U.S. Application Data
(60) Provisional application No. 63/702,198, filed on Oct. 2, 2024.

(51) Int. Cl. G11C 16/34; G11C 29/00; G11C 29/52

(52) U.S. Cl. CPC G11C 16/349; G11C 29/52; G11C 29/883; G11C 2211/4062

(57) ABSTRACT

In some implementations, a memory apparatus may identify a retirement condition for a block of one or more blocks of the memory apparatus, the retirement condition based on an average maintenance metric of the one or more blocks. The memory apparatus may retire the block based on a determination that a maintenance metric of the block satisfies the retirement condition.

### CROSS-REFERENCE TO RELATED APPLICATION

This patent application claims priority to U.S. Provisional Patent Application No. 63/702,198, filed on Oct. 2, 2024, entitled “MAINTENANCE-BASED CONDITIONS FOR BLOCK RETIREMENT,” and assigned to the assignee hereof. The disclosure of the prior application is considered part of and is incorporated by reference into this patent application.

### TECHNICAL FIELD

The present disclosure generally relates to memory devices, memory device operations, and, for example, to maintenance-based conditions for block retirement.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system capable of maintenance-based conditions for block retirement.

FIG. 2 is a diagram illustrating an example memory architecture that may be used by the memory device.

FIG. 3 is a diagram of an example process that supports maintenance-based conditions for block retirement.

FIG. 4 is a flowchart of an example method associated with maintenance-based conditions for block retirement.

FIG. 5 is a flowchart of an example method associated with maintenance-based conditions for block retirement.

FIG. 6 is a flowchart of an example method associated with maintenance-based conditions for block retirement.

FIG. 7 is a flowchart of an example method associated with maintenance-based conditions for block retirement.

### DETAILED DESCRIPTION

In some memory systems, such as NAND or other non-volatile memory systems, some blocks of memory cells may degrade at a relatively rapid rate compared to other blocks. For example, some blocks may exhibit an increased sensitivity to program cycles, erase cycles, and/or read cycles, and thus may experience higher wear from operation. Such blocks may pass standard manufacturing tests or initial usage, but may demonstrate an accelerated degradation pattern during operation, which may result in an unusually high rate of maintenance operations. For example, the memory system may perform refresh operations and/or error control operations on such blocks more frequently than other blocks. Although these blocks may be successfully used by the memory system (e.g., such blocks may not trigger failure conditions such as write failures and/or uncorrectable errors), the increased rate of maintenance operations may consume system resources and thus reduce the performance of the memory system. Further, such blocks may be at an increased risk of early failure, which may lead to uncorrectable errors and thus reduce system reliability.

Some implementations as described herein may enable maintenance-based conditions for block retirement. For example, a memory system may determine whether to retire a block of memory cells based on a maintenance metric of the block of memory cells. A maintenance metric may include parameters indicative of the health and operational status of the block, such as a frequency of refresh operations, error control operations, and/or other maintenance activities performed on the block. For example, if the maintenance metric of a block is significantly greater than the average maintenance metric of other blocks of the memory system, the memory system may determine that the block exhibits higher-than-average degradation. Additionally, or alternatively, if the maintenance metric of the block is significantly greater than an expected maintenance metric for the block (e.g., a typical maintenance metric based on the age of the block), then the memory system may determine that the block exhibits higher-than-average degradation.

Accordingly, the memory system may retire the block, such as by transferring data stored in the block to another block of memory cells within the memory system and marking the original block as retired. This retirement process may include transferring data from the block to another block of the memory system, updating a logical-to-physical mapping associated with the data, and/or disabling write operations to the retired block.

By retiring a block based on the maintenance metric of the block, the memory system may improve system reliability and/or performance. For example, by proactively identifying and retiring blocks that exhibit signs of early degradation, the memory system may mitigate future data corruption, such as uncorrectable errors, that may occur if these blocks remain in use. Additionally, by retiring degraded blocks, the memory system may free-up system resources that would otherwise be consumed by frequent maintenance operations. For example, blocks that undergo frequent refresh and/or error control operations may consume processing power and memory bandwidth, which may negatively impact the overall performance of the memory apparatus. By retiring these blocks, the memory apparatus may more efficiently allocate resources, leading to improved data access times.

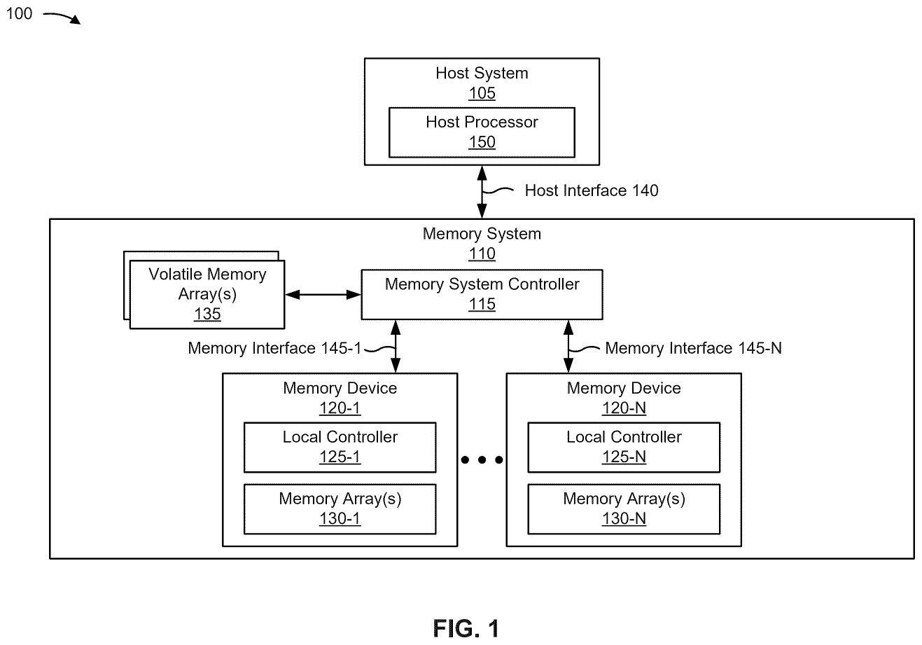

FIG. 1 is a diagram illustrating an example system 100 capable of maintenance-based conditions for block retirement. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may be configured to identify a retirement condition for a block of one or more blocks of the memory device, the retirement condition based on an average maintenance metric of the one or more blocks; and retire the block based on a determination that a maintenance metric of the block satisfies the retirement condition.

In some implementations, one or more systems, devices, apparatuses, components, and/or controllers of FIG. 1 may be configured to identify a retirement condition for a block of one or more blocks of a memory apparatus, the retirement condition based on an average degradation metric of the one or more blocks; and retire the block based on determining that a degradation metric of the block satisfies the retirement condition.

In some implementations, one or more systems, devices, apparatuses, components, and/or controllers of FIG. 1 may be configured to identify a retirement condition for a block of one or more blocks of the memory device; and retire the block based on a determination that a refresh metric of the block satisfies the retirement condition, the refresh metric based on a quantity of refresh operations performed on the block.

In some implementations, one or more systems, devices, apparatuses, components, and/or controllers of FIG. 1 may be configured to identify a retirement condition for a block of one or more blocks of the memory device; and retire the block based on a determination that an error control metric of the block satisfies the retirement condition, the error control metric based on a quantity of error control operations performed on the block.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

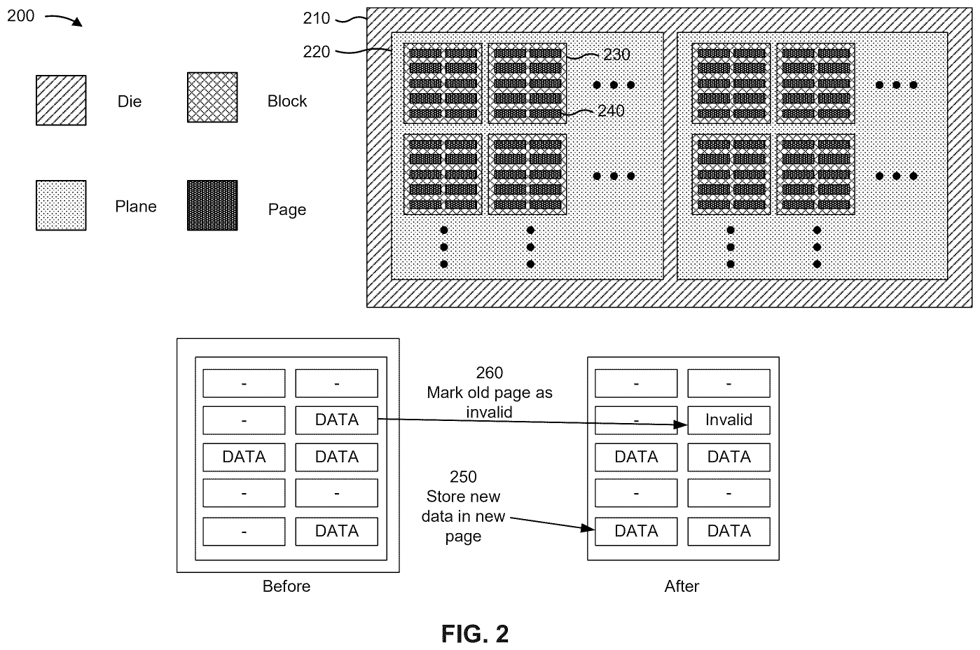

FIG. 2 is a diagram illustrating an example memory architecture 200 that may be used by the memory device 120. The memory device 120 may use the memory architecture 200 to store data. As shown, the memory architecture 200 may include a die 210, which may include multiple planes 220. A plane 220 may include multiple blocks 230. A block 230 may include multiple pages 240. Although FIG. 2 shows a particular quantity of planes 220 per die 210, a particular quantity of blocks 230 per plane 220, and a particular quantity of pages 240 per block 230, these quantities may be different than what is shown. In some implementations, the memory architecture 200 is a NAND memory architecture.

The die 210 is a structure made of semiconductor material, such as silicon. In some implementations, a die 210 is the smallest unit of memory that can independently execute commands. A memory device 120 may include one or more dies 210. In some implementations, the memory device 120 may include multiple dies 210. In this case, multiples dies 210 may each perform a respective memory operation (e.g., a read operation, a write operation, or an erase operation) in parallel. For example, a local controller 125 of the memory device 120 may be configured to concurrently perform memory operations on multiple dies 210 for parallel control.

Each die 210 of a memory device 120 includes one or more planes 220. A plane 220 is sometimes called a memory plane. In some implementations, identical and concurrent operations can be performed on multiple planes 220 (sometimes with restrictions). For example, a multi-plane command (e.g., a multi-plane read command or a multi-plane write command) may be executed on multiple planes 220 concurrently, whereas a single plane command (e.g., a single plane read command or a single plane write command) may be executed on a single plane 220. A logical unit of the memory device 120 may include one or more planes 220 of a die 210. In some implementations, a logical unit may include all planes 220 of a die 210 and may be equivalent to a die 210. Alternatively, a logical unit may include fewer than all planes 220 of a die 210. A logical unit may be identified by a logical unit number (LUN). Depending on the context, the term “LUN” may refer to a logical unit or an identifier (e.g., a number) of that logical unit.

Each plane 220 includes multiple blocks 230. A block 230 is sometimes called a memory block. Each block 230 includes multiple pages 240. A page 240 is sometimes called a memory page. A block 230 is the smallest unit of memory that can be erased. In other words, an individual page 240 of a block 230 cannot be erased without erasing every other page 240 of the block 230. A page 240 is the smallest unit of memory to which data can be written (i.e., the smallest unit of memory that can be programmed with data). The terminology “programming” memory and “writing to” memory may be used interchangeably. A page 240 may include multiple memory cells that are accessible via the same access line (sometimes called a word line). In some implementations, a block 230 may be divided into multiple sub-blocks. A sub-block is a portion of a block 230 and may include a subset of pages 240 of the block and/or a subset of memory cells of the block 230.

In some implementations, read and write operations are performed for a specific page 240, while erase operations are performed for a block 230 (e.g., all pages 240 in the block 230). In some implementations, to prevent wearing out of memory, all pages 240 of a block 230 may be programmed before the block 230 is erased to enable a new program operation to be performed to a page 240 of the block 230. After a page 240 is programmed with data (called “old data” below), that data can be erased, but that data cannot be overwritten with new data prior to being erased. The erase operation would erase all pages 240 in the block 230, and erasing the entire block 230 every time that new data is to replace old data would quickly wear out the memory cells of the block 230. Thus, rather than performing an erase operation, the new data may be stored in a new page (e.g., an empty page), as shown by reference number 250, and the old page that stores the old data may be marked as invalid, as shown by reference number 260. The memory device 120 may then point operations associated with the data to the new page (e.g., in an address table) and may track invalid pages to prevent program operations from being performed on invalid pages prior to an erase operation.

When a block 230 satisfies an erasure condition, the memory device 120 may select the block 230 for erasure, copy the valid data of the block 230 (e.g., to a new block 230 or to the same block 230 after erasure), and erase the block 230. For example, the erasure condition may be that all pages 240 of the block 230 or a threshold quantity or percentage of pages 240 of the block 230 are unavailable for further programming (e.g., are either invalid or already store valid data). As another example, the erasure condition may be that a quantity or percentage of free pages 240 of the block 230 (e.g., pages 240 that are available to be written) is less than or equal to a threshold. The process of selecting a block 230 satisfying an erasure condition, copying valid pages 240 of that block 230 to a new block 230 (or the same block 230 after erasure), and erasing the block 230 is sometimes called garbage collection and is used to free up memory space of the memory device 120.

In some examples, a memory apparatus, such as the memory system 110 and/or a memory device 120, may determine whether to retire a block 230 based on a maintenance metric of the block 230. For example, the memory apparatus may track maintenance metrics of a block 230, such as a quantity of refresh operations performed on a block 230 and/or a quantity of error control operations performed on a block 230. The memory apparatus may track such metrics using one or more counters managed by a controller, such as the memory system controller 115 and/or a local controller 125. If the maintenance metric of a block 230 is significantly greater than the average maintenance metric of other blocks 230 of the memory apparatus, the memory apparatus may determine that the block 230 exhibits higher-than-average degradation. Additionally, or alternatively, if the maintenance metric of the block 230 is significantly greater than an expected maintenance metric for the block 230 (e.g., a typical maintenance metric based on the age of the block 230), then the memory apparatus may determine that the block 230 exhibits higher-than-average degradation. Accordingly, the memory apparatus may retire the block 230, such as by transferring data stored in the block 230 to another block 230 within the memory apparatus and marking the original block 230 as retired.

As indicated above, FIG. 2 is provided as an example. Other examples may differ from what is described with regard to FIG. 2.

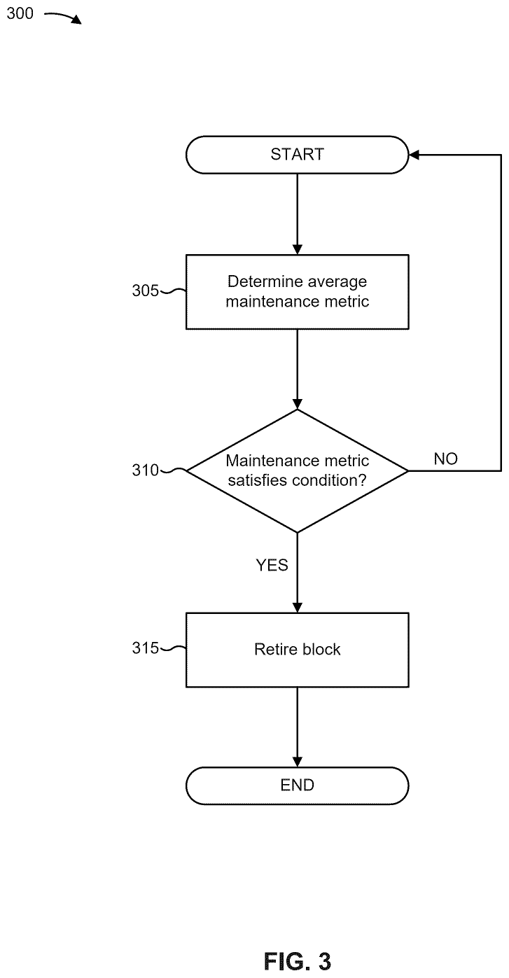

FIG. 3 is a diagram of an example process 300 that supports maintenance-based conditions for block retirement. Aspects of the process 300 may be implemented by a memory apparatus, such as a memory system 110 and/or one or more memory devices 120. In some examples, aspects of the process 300 may be implemented by one or more controllers, such as a memory system controller 115 and/or one or more local controllers 125.

The process 300 may include a method to determine whether to retire a block of memory cells based on a maintenance metric of the block. A maintenance metric of a block may be a metric indicative of the operational health and longevity of the block within the memory apparatus, such as a quantity of maintenance operations that the memory apparatus has performed on the block. Additionally, or alternatively, the maintenance metric of a block may indicate a degradation metric of the block, such as a quantity of access operations performed on the block. In some examples, the maintenance metric may further be based on a duration, such as a quantity of maintenance operations performed within a time period. Said another way, the maintenance metric may be a rate (e.g., a frequency) at which the memory apparatus performs maintenance operations on the block.

For example, the maintenance metric may be based on a refresh metric, such as a quantity of refresh operations performed on the block. A refresh operation may be an operation performed by the memory system to refresh the charges of memory cells within the block to prevent data loss. For example, memory cells of a block may lose charge due to leakage, which may lead to data corruption. Accordingly, if the memory apparatus detects sufficient leakage (e.g., if the average charges of memory cells in a block have decreased by a threshold), the memory apparatus may perform a refresh operation on the block.

Additionally, or alternatively, the maintenance metric may be based on an error control metric, such as a quantity of error control operations performed on the block. An error control operation may be an operation performed by the memory apparatus to correct errors detected during access operations. For example, the memory apparatus may calculate one or more error correction codes (ECCs) to detect and/or correct single-bit or multi-bit errors in data stored within a block. The memory apparatus may perform an error control operation on a block based on, in response to, or otherwise associated with detecting a threshold quantity of errors in the block. Accordingly, a relatively high error control metric may indicate that the block has frequently encountered data integrity issues and thus may indicate rapid degradation and diminished reliability of the block.

As shown by reference number 305, the memory apparatus may identify a retirement condition for a block of one or more blocks of the memory apparatus based on a maintenance metric of the block. To identify the retirement condition, the memory apparatus may determine an average maintenance metric (e.g., an average degradation metric, an average refresh metric, and/or an average error control metric) across blocks of the memory apparatus (e.g., an average of one or more maintenance metrics corresponding to one or more blocks of the memory apparatus).

Additionally, or alternatively, the memory apparatus may determine an expected maintenance metric (e.g., an expected refresh metric and/or an expected error control metric) across the blocks of the memory apparatus. An expected maintenance metric may be a benchmark or reference value that represents anticipated behavior of a block. The expected maintenance metric may be based on statistical analysis of historical data, simulations, or other results obtained during testing and qualification phases of the memory apparatus. For example, an expected refresh metric may be calculated based on the average number of refresh operations used for blocks of memory cells over a defined period. Similarly, an expected error control metric may be based on an average number of error control operations performed on blocks during read, write, and/or erase cycles under similar conditions.

The memory apparatus may further identify a retirement threshold associated with the retirement condition. The retirement threshold may indicate whether a block exhibits increased degradation. For example, if the difference between the maintenance metric and the average and/or expected maintenance metric is greater than the retirement threshold, then the memory apparatus may determine that the block exhibits increased degradation.

In some examples, the retirement threshold may be different for different types of memory cells. For example, different types of memory cells, such as single-level cells (SLCs), multi-level cells (MLCs), triple-level cells (TLCs), and/or quad-level cells (QLCs), among other examples, may exhibit different endurance and degradation characteristics. Accordingly, a retirement threshold for a block of memory cells of a first type (e.g., an SLC block) may be different (e.g., higher) than a retirement threshold for a block of memory cells or a second type (e.g., an MLC block).

In some implementations, the memory apparatus may configure the retirement threshold based on input from a host system. For example, a host system may provide, and the memory apparatus may obtain, a configuration command indicating a retirement threshold for a block of memory cells. The host system may configure the retirement threshold for a block based on application usage of the block. For example, the host system may indicate a lower threshold for applications associated with high data integrity, such as database storage, while specifying a higher threshold for less critical applications, such as temporary file storage.

As shown by reference number 310, the memory apparatus may determine whether the maintenance metric satisfies the retirement condition. For example, the memory apparatus may identify a difference between the maintenance metric and the average maintenance metric. Additionally, or alternatively, the memory apparatus may identify a difference between the maintenance metric and the expected maintenance metric. The memory apparatus may compare the difference to the retirement threshold. If the difference satisfies the retirement threshold (e.g., if the difference is greater than the retirement threshold), then the memory apparatus may determine that the maintenance metric satisfies the retirement condition. If the difference does not satisfy the retirement threshold (e.g., if the difference is less than and/or equal to the retirement threshold), then the memory apparatus may determine that the maintenance metric does not satisfy the retirement condition.

If the maintenance metric satisfies the retirement condition, then, as shown by reference number 315, the memory apparatus may retire the block. For example, the memory apparatus may add the block to a retired block pool, such as by storing an indication of the block to a retired block list. In some implementations, the memory apparatus may mark the block as a “read-only” block. In such implementations, the memory apparatus may continue to read data from the block and may not program new data to the block. Alternatively, the memory apparatus may mark the block as unusable and may transfer data stored to the block to other available blocks within the memory apparatus. In some cases, retiring a block may include updating a wear leveling table or other data structures that monitor the health and usage statistics of blocks of the memory system.

Alternatively, if the maintenance metric does not satisfy the retirement condition, then the memory apparatus may refrain from retiring the block. In some examples, the memory apparatus may periodically perform aspects of the process 300. For example, the memory apparatus may execute the process 300 as part of a scheduled memory management operation for the block of memory cells. This periodic execution may allow the memory apparatus to continually monitor and evaluate the health and reliability of each block.

By retiring a block based on the maintenance metric of the block, the memory apparatus may improve system reliability and/or performance. For example, the memory apparatus may proactively identify and retire blocks that exhibit signs of early degradation, such as a high frequency of refresh operations or error control operations. This preemptive retirement may mitigate future data corruption, such as uncorrectable errors, that may occur if these blocks remain in use. Additionally, by retiring degraded blocks, the memory apparatus may free-up system resources that would otherwise be consumed by frequent maintenance operations. For example, blocks that undergo frequent refresh and/or error control operations may consume processing power and memory bandwidth, which may negatively impact the overall performance of the memory apparatus. By retiring these blocks, the memory apparatus may more efficiently allocate resources, leading to improved data access times.

As indicated above, FIG. 3 is provided as an example. Other examples may differ from what is described with regard to FIG. 3.

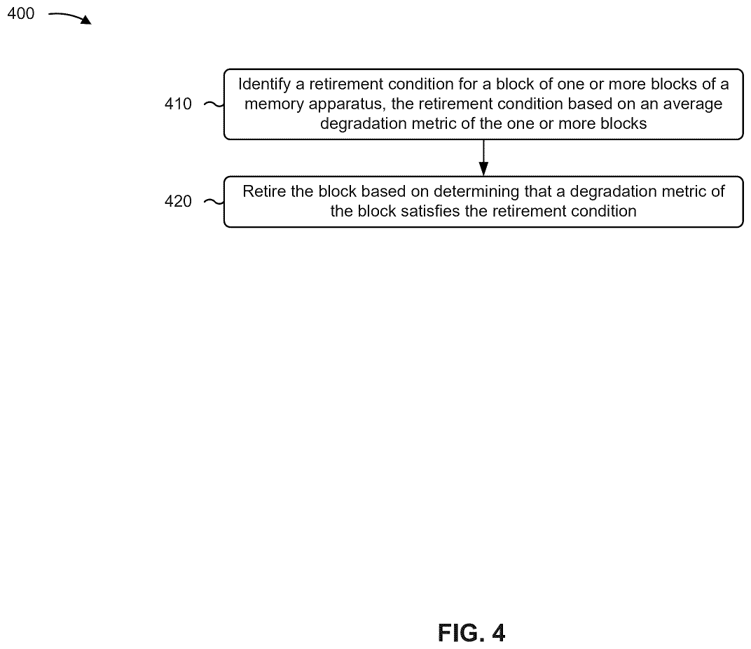

FIG. 4 is a flowchart of an example method 400 associated with maintenance-based conditions for block retirement. In some implementations, a memory apparatus (e.g., the memory system 110 and/or one or more memory devices 120) may perform or may be configured to perform the method 400. In some implementations, another device or a group of devices separate from or including the memory apparatus (e.g., the host system 105) may perform or may be configured to perform the method 400. Additionally, or alternatively, one or more components of the memory apparatus (e.g., a memory system controller 115, one or more memory interfaces 145, one or more local controllers 125, one or more memory arrays 130, and/or one or more volatile memory arrays 135) may perform or may be configured to perform the method 400. Thus, means for performing the method 400 may include the memory apparatus and/or one or more components of the memory apparatus. Additionally, or alternatively, a non-transitory computer-readable medium may store one or more instructions that, when executed by the memory apparatus, cause the memory apparatus to perform the method 400.

As shown in FIG. 4, the method 400 may include identifying a retirement condition for a block of one or more blocks of a memory apparatus, the retirement condition based on an average degradation metric of the one or more blocks (block 410). As further shown in FIG. 4, the method 400 may include retiring the block based on determining that a degradation metric of the block satisfies the retirement condition (block 420).

The method 400 may include additional aspects, such as any single aspect or any combination of aspects described below and/or described in connection with one or more other methods or operations described elsewhere herein.

In a first aspect, determining that the degradation metric of the block satisfies the retirement condition comprises determining that a difference of the degradation metric and the average degradation metric satisfies a threshold.

In a second aspect, alone or in combination with the first aspect, the method 400 includes identifying the threshold based on a type of memory cell included in the block.

In a third aspect, alone or in combination with one or more of the first and second aspects, the method 400 includes configuring the threshold based on a configuration command obtained from a host system.

Although FIG. 4 shows example blocks of a method 400, in some implementations, the method 400 may include additional blocks, fewer blocks, different blocks, or differently arranged blocks than those depicted in FIG. 4. Additionally, or alternatively, two or more of the blocks of the method 400 may be performed in parallel. The method 400 is an example of one method that may be performed by one or more devices described herein. These one or more devices may perform or may be configured to perform one or more other methods based on operations described herein.

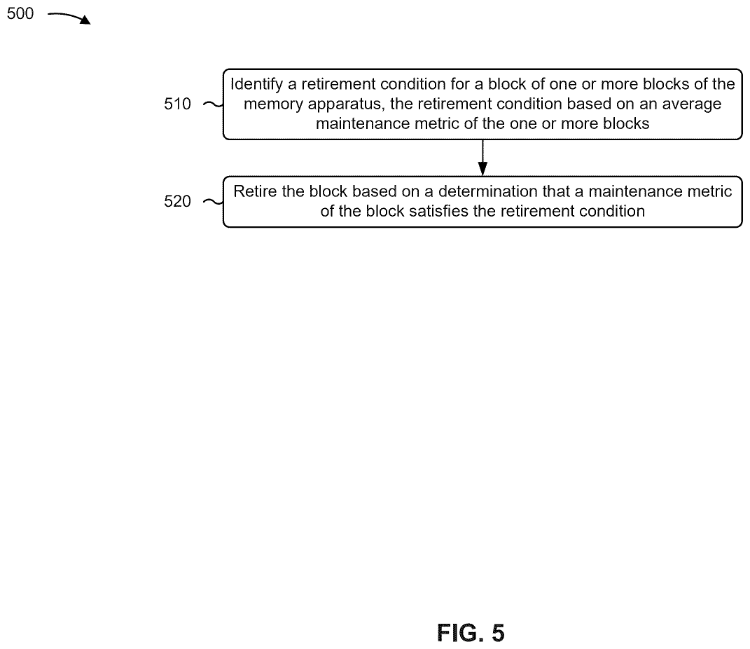

FIG. 5 is a flowchart of an example method 500 associated with maintenance-based conditions for block retirement. In some implementations, a memory apparatus (e.g., the memory system 110 and/or one or more memory devices 120) may perform or may be configured to perform the method 500. In some implementations, another device or a group of devices separate from or including the memory apparatus (e.g., the host system 105) may perform or may be configured to perform the method 500. Additionally, or alternatively, one or more components of the memory apparatus (e.g., a memory system controller 115, one or more memory interfaces 145, one or more local controllers 125, one or more memory arrays 130, and/or one or more volatile memory arrays 135) may perform or may be configured to perform the method 500. Thus, means for performing the method 500 may include the memory apparatus and/or one or more components of the memory apparatus. Additionally, or alternatively, a non-transitory computer-readable medium may store one or more instructions that, when executed by the memory apparatus, cause the memory apparatus to perform the method 500.

As shown in FIG. 5, the method 500 may include identifying a retirement condition for a block of one or more blocks of the memory apparatus, the retirement condition based on an average maintenance metric of the one or more blocks (block 510). As further shown in FIG. 5, the method 500 may include retiring the block based on a determination that a maintenance metric of the block satisfies the retirement condition (block 520).

The method 500 may include additional aspects, such as any single aspect or any combination of aspects described below and/or described in connection with one or more other methods or operations described elsewhere herein.

In a first aspect, determining that the maintenance metric of the block satisfies the retirement condition comprises determining that a difference of the maintenance metric and the average maintenance metric satisfies a threshold.

In a second aspect, alone or in combination with the first aspect, the method 500 includes identifying the threshold based on a type of memory cell included in the block.

In a third aspect, alone or in combination with one or more of the first and second aspects, the method 500 includes configuring the threshold based on a configuration command obtained from a host system.

In a fourth aspect, alone or in combination with one or more of the first through third aspects, the block includes one or more non-volatile memory cells.

In a fifth aspect, alone or in combination with one or more of the first through fourth aspects, the maintenance metric is based on a quantity of refresh operations performed on the block.

In a sixth aspect, alone or in combination with one or more of the first through fifth aspects, the maintenance metric is based on a quantity of error control operations performed on the block.

Although FIG. 5 shows example blocks of a method 500, in some implementations, the method 500 may include additional blocks, fewer blocks, different blocks, or differently arranged blocks than those depicted in FIG. 5. Additionally, or alternatively, two or more of the blocks of the method 500 may be performed in parallel. The method 500 is an example of one method that may be performed by one or more devices described herein. These one or more devices may perform or may be configured to perform one or more other methods based on operations described herein.

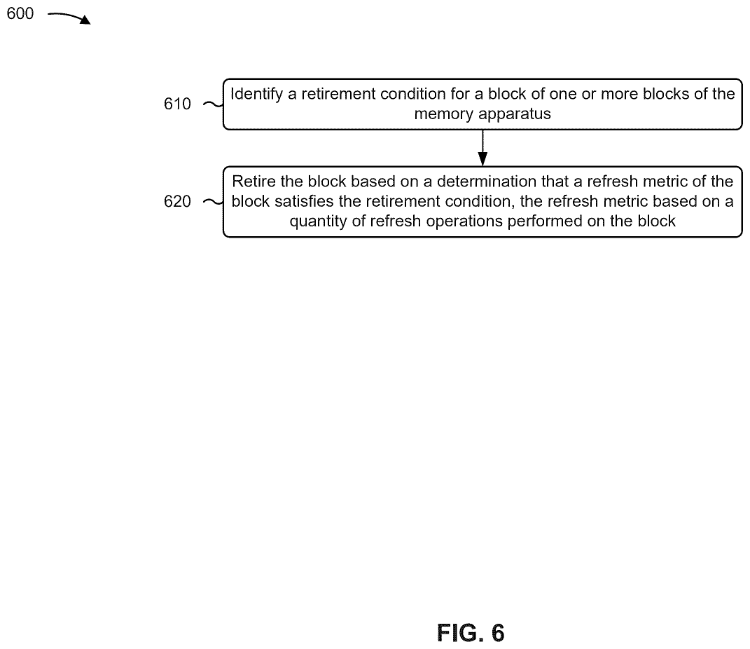

FIG. 6 is a flowchart of an example method 600 associated with maintenance-based conditions for block retirement. In some implementations, a memory apparatus (e.g., the memory system 110 and/or one or more memory devices 120) may perform or may be configured to perform the method 600. In some implementations, another device or a group of devices separate from or including the memory apparatus (e.g., the host system 105) may perform or may be configured to perform the method 600. Additionally, or alternatively, one or more components of the memory apparatus (e.g., a memory system controller 115, one or more memory interfaces 145, one or more local controllers 125, one or more memory arrays 130, and/or one or more volatile memory arrays 135) may perform or may be configured to perform the method 600. Thus, means for performing the method 600 may include the memory apparatus and/or one or more components of the memory apparatus. Additionally, or alternatively, a non-transitory computer-readable medium may store one or more instructions that, when executed by the memory apparatus, cause the memory apparatus to perform the method 600.

As shown in FIG. 6, the method 600 may include identifying a retirement condition for a block of one or more blocks of the memory apparatus (block 610). As further shown in FIG. 6, the method 600 may include retiring the block based on a determination that a refresh metric of the block satisfies the retirement condition, the refresh metric based on a quantity of refresh operations performed on the block (block 620).

The method 600 may include additional aspects, such as any single aspect or any combination of aspects described below and/or described in connection with one or more other methods or operations described elsewhere herein.

In a first aspect, identifying the retirement condition comprises identifying an average refresh metric of the one or more blocks of the memory apparatus.

In a second aspect, alone or in combination with the first aspect, determining that the refresh metric satisfies the retirement condition comprises determining that a difference of the refresh metric and the average refresh metric satisfies a threshold.

In a third aspect, alone or in combination with one or more of the first and second aspects, identifying the retirement condition comprises identifying an expected refresh metric of the block based on an age of the block.

In a fourth aspect, alone or in combination with one or more of the first through third aspects, determining that the refresh metric satisfies the retirement condition comprises determining that a difference of the refresh metric and the expected refresh metric satisfies a threshold.

In a fifth aspect, alone or in combination with one or more of the first through fourth aspects, the refresh metric is a refresh rate based on the quantity of refresh operations performed during a duration, wherein the duration is based on a duration parameter stored by the memory device.

Although FIG. 6 shows example blocks of a method 600, in some implementations, the method 600 may include additional blocks, fewer blocks, different blocks, or differently arranged blocks than those depicted in FIG. 6. Additionally, or alternatively, two or more of the blocks of the method 600 may be performed in parallel. The method 600 is an example of one method that may be performed by one or more devices described herein. These one or more devices may perform or may be configured to perform one or more other methods based on operations described herein.

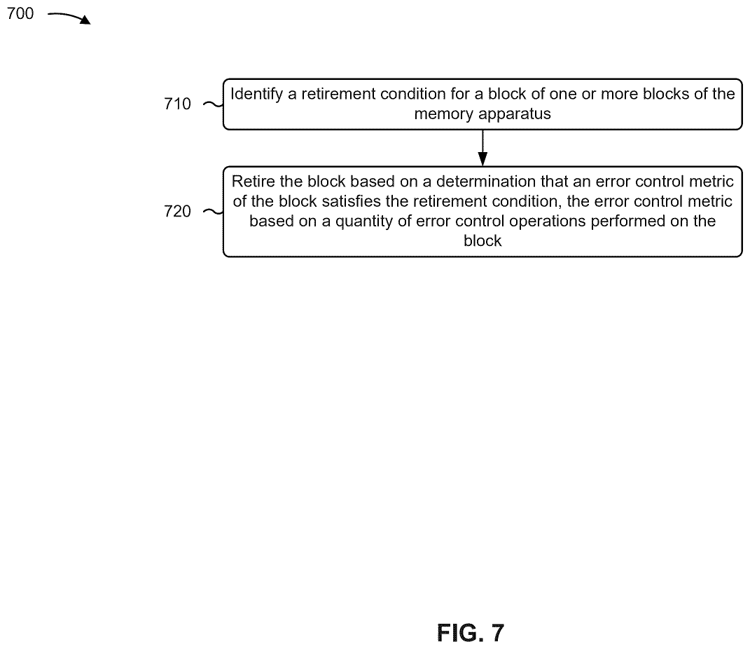

FIG. 7 is a flowchart of an example method 700 associated with maintenance-based conditions for block retirement. In some implementations, a memory apparatus (e.g., the memory system 110 and/or one or more memory devices 120) may perform or may be configured to perform the method 700. In some implementations, another device or a group of devices separate from or including the memory apparatus (e.g., the host system 105) may perform or may be configured to perform the method 700. Additionally, or alternatively, one or more components of the memory apparatus (e.g., a memory system controller 115, one or more memory interfaces 145, one or more local controllers 125, one or more memory arrays 130, and/or one or more volatile memory arrays 135) may perform or may be configured to perform the method 700. Thus, means for performing the method 700 may include the memory apparatus and/or one or more components of the memory apparatus. Additionally, or alternatively, a non-transitory computer-readable medium may store one or more instructions that, when executed by the memory apparatus, cause the memory apparatus to perform the method 700.

As shown in FIG. 7, the method 700 may include identifying a retirement condition for a block of one or more blocks of the memory apparatus (block 710). As further shown in FIG. 7, the method 700 may include retiring the block based on a determination that an error control metric of the block satisfies the retirement condition, the error control metric based on a quantity of error control operations performed on the block (block 720).

The method 700 may include additional aspects, such as any single aspect or any combination of aspects described below and/or described in connection with one or more other methods or operations described elsewhere herein.

In a first aspect, identifying the retirement condition comprises identifying an average error control metric of the one or more blocks of the memory device.

In a second aspect, alone or in combination with the first aspect, determining that the error control metric satisfies the retirement condition comprises determining that a difference of the error control metric and the average error control metric satisfies a threshold.

In a third aspect, alone or in combination with one or more of the first and second aspects, identifying the retirement condition comprises identifying an expected error control metric of the block based on an age of the block.

In a fourth aspect, alone or in combination with one or more of the first through third aspects, determining that the error control metric satisfies the retirement condition comprises determining that a difference of the error control metric and the expected error control metric satisfies a threshold.

In a fifth aspect, alone or in combination with one or more of the first through fourth aspects, the error control metric is an error control rate based on the quantity of error control operations performed during a duration, wherein the duration is based on a duration parameter stored by the memory device.

Although FIG. 7 shows example blocks of a method 700, in some implementations, the method 700 may include additional blocks, fewer blocks, different blocks, or differently arranged blocks than those depicted in FIG. 7. Additionally, or alternatively, two or more of the blocks of the method 700 may be performed in parallel. The method 700 is an example of one method that may be performed by one or more devices described herein. These one or more devices may perform or may be configured to perform one or more other methods based on operations described herein.

In some implementations, a memory device includes one or more components configured to: identify a retirement condition for a block of one or more blocks of the memory device, the retirement condition based on an average maintenance metric of the one or more blocks; and retire the block based on a determination that a maintenance metric of the block satisfies the retirement condition.

In some implementations, a method includes identifying a retirement condition for a block of one or more blocks of a memory apparatus, the retirement condition based on an average degradation metric of the one or more blocks; and retiring the block based on determining that a degradation metric of the block satisfies the retirement condition.

In some implementations, a memory device includes one or more components configured to: identify a retirement condition for a block of one or more blocks of the memory device; and retire the block based on a determination that a refresh metric of the block satisfies the retirement condition, the refresh metric based on a quantity of refresh operations performed on the block.

In some implementations, a memory device includes one or more components configured to: identify a retirement condition for a block of one or more blocks of the memory device; and retire the block based on a determination that an error control metric of the block satisfies the retirement condition, the error control metric based on a quantity of error control operations performed on the block.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
one or more components configured to:
identify a retirement condition for a block of one or more blocks of the memory device, the retirement condition based on an average maintenance metric of the one or more blocks; and
retire the block based on a determination that a maintenance metric of the block satisfies the retirement condition.

2. The memory device of claim 1, wherein, to determine that the maintenance metric of the block satisfies the retirement condition, the one or more components are configured to:
determine that a difference of the maintenance metric and the average maintenance metric satisfies a threshold.

3. The memory device of claim 2, wherein the one or more components are further configured to:
identify the threshold based on a type of memory cell included in the block.

4. The memory device of claim 2, wherein the one or more components are further configured to:
configure the threshold based on a configuration command obtained from a host system.

5. The memory device of claim 1, wherein the block includes one or more non-volatile memory cells.

6. The memory device of claim 1, wherein the maintenance metric is based on a quantity of refresh operations performed on the block.

7. The memory device of claim 1, wherein the maintenance metric is based on a quantity of error control operations performed on the block.

8. A method, comprising:
identifying a retirement condition for a block of one or more blocks of a memory apparatus, the retirement condition based on an average degradation metric of the one or more blocks; and
retiring the block based on determining that a degradation metric of the block satisfies the retirement condition.

9. The method of claim 8, wherein determining that the degradation metric of the block satisfies the retirement condition comprises:
determining that a difference of the degradation metric and the average degradation metric satisfies a threshold.

10. The method of claim 9, further comprising:
identifying the threshold based on a type of memory cell included in the block.

11. The method of claim 9, further comprising:
configuring the threshold based on a configuration command obtained from a host system.

12. A memory device, comprising:
one or more components configured to:
identify a retirement condition for a block of one or more blocks of the memory device; and
retire the block based on a determination that a refresh metric of the block satisfies the retirement condition, the refresh metric based on a quantity of refresh operations performed on the block.

13. The memory device of claim 12, wherein, to identify the retirement condition, the one or more components are configured to:
identify an average refresh metric of the one or more blocks of the memory device.

14. The memory device of claim 13, wherein, to determine that the refresh metric satisfies the retirement condition, the one or more components are configured to:
determine that a difference of the refresh metric and the average refresh metric satisfies a threshold.

15. The memory device of claim 12, wherein, to identify the retirement condition, the one or more components are configured to:
identify an expected refresh metric of the block based on an age of the block.

16. The memory device of claim 15, wherein to determine that the refresh metric satisfies the retirement condition, the one or more components are configured to:
determine that a difference of the refresh metric and the expected refresh metric satisfies a threshold.

17. The memory device of claim 12, wherein the refresh metric is a refresh rate based on the quantity of refresh operations performed during a duration, wherein the duration is based on a duration parameter stored by the memory device.

18. A memory device, comprising:
one or more components configured to:
identify a retirement condition for a block of one or more blocks of the memory device; and
retire the block based on a determination that an error control metric of the block satisfies the retirement condition, the error control metric based on a quantity of error control operations performed on the block.

19. The memory device of claim 18, wherein, to identify the retirement condition, the one or more components are configured to:
identify an average error control metric of the one or more blocks of the memory device.

20. The memory device of claim 19, wherein, to determine that the error control metric satisfies the retirement condition, the one or more components are configured to:
determine that a difference of the error control metric and the average error control metric satisfies a threshold.

21. The memory device of claim 18, wherein, to identify the retirement condition, the one or more components are configured to:
identify an expected error control metric of the block based on an age of the block.

22. The memory device of claim 21, wherein to determine that the error control metric satisfies the retirement condition, the one or more components are configured to:
determine that a difference of the error control metric and the expected error control metric satisfies a threshold.

23. The memory device of claim 18, wherein the error control metric is an error control rate based on the quantity of error control operations performed during a duration, wherein the duration is based on a duration parameter stored by the memory device.
